(19) United States
(12) Patent Application Publication
(10) Pub. No.: US 2026/0190340 A1
(43) Pub. Date: Jul. 2, 2026

(54) MEMORY DEVICE AND METHOD OF MANUFACTURING THE SAME

(71) Applicant: MACRONIX International Co., Ltd., Hsinchu (TW)

(72) Inventor: Chen-Wei Lu, Taoyuan City (TW)

(73) Assignee: MACRONIX International Co., Ltd., Hsinchu (TW)

(21) Appl. No.: 19/002,333

(22) Filed: Dec. 26, 2024

(51) Int. Cl. H10B 43/27; H10B 43/10

(52) U.S. Cl. CPC H10B 43/27; H10B 43/10

(57) ABSTRACT

A memory device includes a stacked structure, a vertical channel pillar, a first plug and a second plug. The stacked structure includes a plurality of insulating layers and a plurality of conductive layers that are alternately stacked. The vertical channel pillar vertically penetrates the stacked structure, wherein the vertical channel pillar includes an insulating column, a channel layer surrounding the insulating column, and a charge storage structure surrounding the channel layer. The first plug and the second plug are arranged on both sides of the insulating column and connected to the channel layer. In a top view, a distance between a center of the first plug and a center of the second plug is greater than a radius of the vertical channel pillar.

### BACKGROUND

### Technical Field

The disclosure relates to a memory device and a method of manufacturing the same.

### Description of Related Art

Non-volatile memory devices have the advantage that stored data will not disappear even after a power outage. Therefore, non-volatile memory devices have become a memory device widely used in personal computers and other electronic apparatus.

Currently, in order to further enhance the integration density of memory devices, a three-dimensional (3D) memory has been developed. However, due to the continuous miniaturization of semiconductor devices, numerous challenges pertaining to three-dimensional memory persist.

### SUMMARY

A memory device and a method of manufacturing the same, which may improve the local bit line (LBL) open issue without causing LBL short yield loss, and may shrink the vertical channel pillar to gain more density, are provided in the disclosure.

In an embodiment of the disclosure, a memory device at least includes a stacked structure, a vertical channel pillar, a first plug, and a second plug. The stacked structure includes insulating layers and conductive layers that are alternately stacked. The vertical channel pillar vertically penetrates the stacked structure, in which the vertical channel pillar includes an insulating column, a channel layer surrounding the insulating column, and a charge storage structure surrounding the channel layer. The first plug and the second plug are arranged on both sides of the insulating column and connected to the channel layer. In a top view, a distance between a center of the first plug and a center of the second plug is greater than a radius of the vertical channel pillar.

In an embodiment of the disclosure, a method of manufacturing a memory device includes the following steps. A stacked structure is formed, in which the stacked structure includes insulating layers and sacrificial layers that are alternately stacked. A vertical channel pillar penetrating the stacked structure is formed, in which the vertical channel pillar includes an insulating column, a channel layer surrounding the insulating column, and a charge storage structure surrounding the channel layer. A first plug and a second plug are formed on both sides of the insulating column, in which the first plug and second plug are connected to the channel layer, and a distance between a center of the first plug and a center of the second plug is greater than a radius of the vertical channel pillar. A gate replacement process is performed to replace the sacrificial layers with conductive layers.

Based on the above, at least one of the first plug and the second plug in the embodiment of the disclosure is located beyond the range of the vertical channel pillar. Therefore, it is possible to improve the LBL open issue while simultaneously without causing LBL short yield loss, and to shrink the vertical channel pillar, thereby achieving higher memory density.

### BRIEF DESCRIPTION OF THE DRAWINGS

FIG. 1A is a section view of a memory device according to an embodiment of the disclosure.

FIG. 1B is a top view of line B-B′ in FIG. 1A.

FIG. 2A is a section view of another memory device according to an embodiment of the disclosure.

FIG. 2B is a top view of line B-B′ in FIG. 2A.

FIG. 3A, FIG. 4A, FIG. 5A, FIG. 6A, FIG. 7A, FIG. 8A, FIG. 9A, and FIG. 10A are section views of a manufacturing process of a memory device according to an embodiment of the disclosure.

FIG. 3B, FIG. 4B, FIG. 5B, FIG. 6B, FIG. 7B, FIG. 8B, FIG. 9B, and FIG. 10B are top views of line B-B′ in FIG. 3A, FIG. 4A, FIG. 5A, FIG. 6A, FIG. 7A, FIG. 8A, FIG. 9A, and FIG. 10A respectively.

FIG. 11A, FIG. 12A, FIG. 13A, FIG. 14A, FIG. 15A, FIG. 16A, and FIG. 17A are section views of a manufacturing process of another memory device according to an embodiment of the disclosure.

FIG. 11B, FIG. 12B, FIG. 13B, FIG. 14B, FIG. 15B, FIG. 16B, and FIG. 17B are top views of line B-B′ in FIG. 11A, FIG. 12A, FIG. 13A, FIG. 14A, FIG. 15A, FIG. 16A, and FIG. 17A respectively.

### DETAILED DESCRIPTION OF DISCLOSED EMBODIMENTS

The concepts of the disclosure may be understood by referring to the following detailed description in conjunction with the accompanying drawings. Furthermore, the dimensions of each region in the drawings are not actual dimensions, and the dimensions between the section view and the top view are not drawn to scale and are for illustration only.

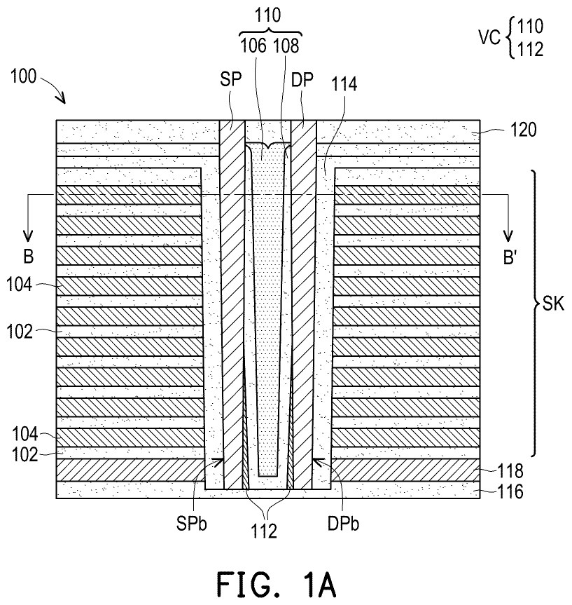

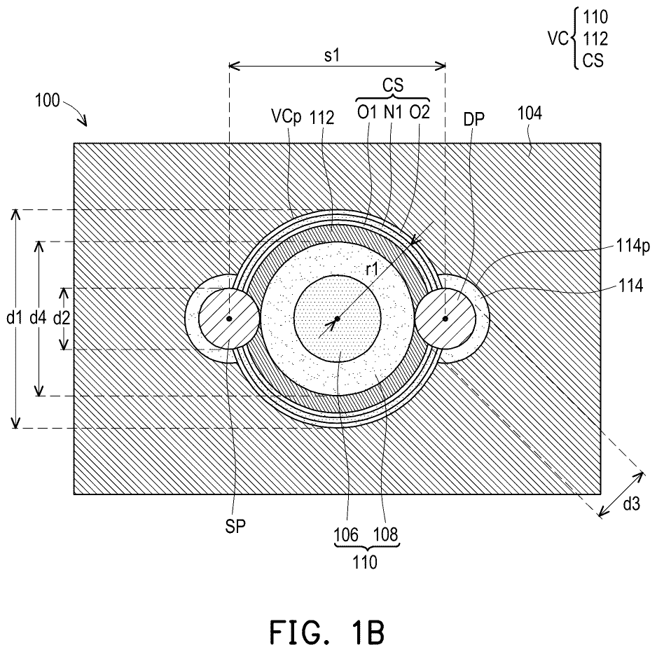

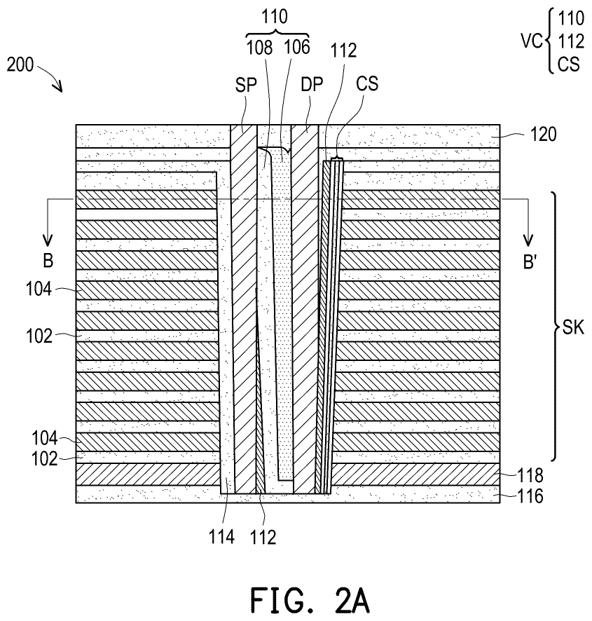

FIG. 1A is a section view of a memory device according to an embodiment of the disclosure. FIG. 1B is a top view of line B-B′ in FIG. 1A.

Referring to FIG. 1A and FIG. 1B, the memory device 100 of this embodiment at least includes a stacked structure SK, a vertical channel pillar VC, a first plug SP, and a second plug DP. The stacked structure SK includes insulating layers 102 and conductive layers 104 that are alternately stacked. That is, the stacked structure SK is composed of layers of insulating layers 102 and conductive layers 104 between the insulating layers 102. In one embodiment, the material of the insulating layer 102 includes silicon oxide. The conductive layer 104 includes, for example, a barrier layer and a metal layer. In one embodiment, the material of the barrier layer includes titanium (Ti), titanium nitride (TiN), tantalum (Ta), tantalum nitride (TaN) or a combination thereof, and the material of the metal layer includes tungsten (W). In some embodiments, polysilicon is first formed at the position of each conductive layer 104 and then replaced by a metal material through a gate replacement process. That is, the conductive layer 104 may be a gate layer in the memory device 100. Each vertical channel pillar VC includes conductively connected memory cells and is coupled to a first plug SP and a second plug DP. The vertical channel pillar VC vertically penetrates the stacked structure SK, in which the vertical channel pillar VC includes an insulating column 110, a channel layer 112 surrounding the insulating column 110, and a charge storage structure CS surrounding the channel layer 112. In this embodiment, the insulating column 110 includes a second insulating pillar 106 and a first insulating pillar 108 surrounding the second insulating pillar 106. In some embodiments, the material of the second insulating pillar 106 is, for example, silicon nitride, and the material of the first insulating pillar 108 is, for example, high quality oxide (HQO), but not limited thereto. In some embodiments, the material of the channel layer 112 includes polysilicon, but not limited thereto. In some embodiments, the charge storage structure CS is an oxide/nitride/oxide (ONO) layer, composed of a nitride layer N1 sandwiched by two oxide layers O1 and O2, but not limited thereto. The first plug SP and the second plug DP are arranged on both sides of the insulating column 110 and connected to the channel layer 112, thereby improving the local bit line (LBL) open issue. In some embodiments, the first plug SP and the second plug DP are opposite to each other and separated by the first insulating pillar 108. In some embodiments, the positions of the first plug SP and the second plug DP are interchangeable and are not limited to those shown in the figures. The first plug SP may be a source plug, and the second plug DP may be a drain plug, but is not limited thereto. In other embodiments, the first plug SP may be a drain plug and the second plug DP may be a source plug.

In the top view of FIG. 1B, the first plug SP and the second plug DP penetrate the charge storage structure CS of the vertical channel pillar VC, and the charge storage structure CS has a discontinuous ring shape due to the embedding of the first plug SP and the second plug DP. The distance s1 between the center of the first plug SP and the center of the second plug DP is greater than the radius r1 of the vertical channel pillar VC, thus ensuring that the first plug SP and the second plug DP are not short-circuited, thereby avoiding LBL short. Compared with other devices in which the first plug SP and the second plug DP are directly arranged inside the vertical channel pillar VC, since the first plug SP and the second plug DP in this embodiment protrude outward from both sides of the vertical channel pillar VC, not only the distance between the first plug SP and the second plug DP can be increased to avoid short circuit, but also the dimension (e.g., the diameter d1) of the vertical channel pillar VC can be reduced, thereby increasing the memory density. In some embodiments, the charge storage structure CS of the vertical channel pillar VC is embedded in the first plug SP and the second plug DP, and the first plug SP and the second plug DP are opposite to each other. In some embodiments, the diameter d1 of the vertical channel pillar VC may be more than 2 times, such as more than 3 times or more than 4 times the diameter d2 of the first plug SP. In some embodiments, the diameter d1 of the vertical channel pillar VC may be more than 2 times, such as more than 3 times or more than 4 times the diameter d3 of the second plug DP. The upper limit of the diameter d1 of the vertical channel pillar VC is determined based on the device density of the memory device 100 and not limited to a specific value.

Continuing to refer to FIG. 1A and FIG. 1B, the memory device 100 further includes an outer insulating layer 114 that surrounds the first plug SP and the second plug DP partially protruding from the outside of the vertical channel pillar VC, so that the first plug SP and the second plug DP are electrically isolated from the conductive layer 104. A perimeter 114p of the outer insulating layer 114 exceeds a perimeter VCp of the vertical channel pillar VC. The outer insulating layer 114 may be in contact with the charge storage structure CS, for example, the outer insulating layer 114 is in direct contact with the oxide layer O2. In this embodiment, the first plug SP and the second plug DP do not overlap with the insulating column 110. That is, the second insulating pillar 106 and the first plug SP are not in contact with each other, and the second insulating pillar 106 is not in contact with the second plug DP. In one embodiment, the diameter d2 of the first plug SP is consistent the diameter d3 of the second plug DP. In another embodiment, the diameter d2 of the first plug SP is different from the diameter d3 of the second plug DP. In FIG. 1A, the stacked structure SK also has a conductive layer 118 formed on the insulating layer 116 underneath, and there is also a dielectric layer 120 above the stacked structure SK, but the disclosure is not limited thereto. In one embodiment, the conductive layer 118 is, for example, doped polysilicon or metal, and the dielectric layer 120 is, for example, an oxide layer. In some embodiments, a diameter d4 of the insulating column 110 is larger than the diameter d2 of the first plug SP and also larger than the diameter d3 of the second plug DP, but is not limited thereto. In some embodiments, the vertical channel pillar VC is conductively coupled to a driving circuit structure (not shown), and the driving circuit structure may include active devices (e.g., transistors) and lines connected to the conductive layer 104 (as word lines). In some embodiments, the channel layer 112 is located between the bottom SPb of the first plug SP and the insulating column 110, and the channel layer 112 is located between the bottom DPb of the second plug DP and the insulating column 110.

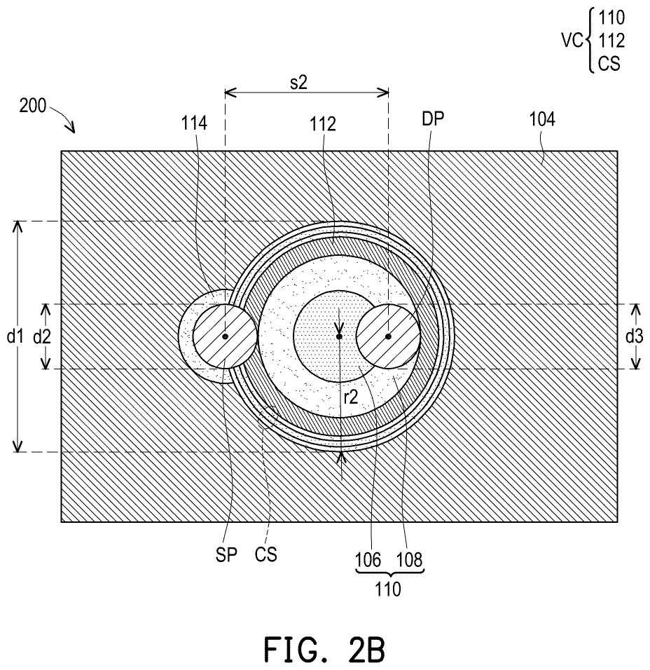

FIG. 2A is a section view of another memory device according to an embodiment of the disclosure. FIG. 2B is a top view of line B-B′ in FIG. 2A. In FIG. 2A and FIG. 2B, the same reference numerals as those in the previous embodiment are used to represent the same or similar parts and components. The relevant content of the same or similar parts and components may be referenced from the contents of the previous embodiment, and are not repeated herein.

Referring to FIG. 2A and FIG. 2B, the main difference between the memory device 200 of this embodiment and the memory device 100 of the previous embodiment lies in the position of the second plug DP. The first plug SP and the second plug DP in the memory device 200 are vertically arranged on both sides of the insulating column 110. The first plug SP penetrates the charge storage structure CS of the vertical channel pillar VC, while the second plug DP does not penetrate the charge storage structure CS. In some embodiments, the positions of the first plug SP and the second plug DP are interchangeable. For example, the second plug DP penetrates the charge storage structure CS, while the first plug SP does not penetrate the charge storage structure CS. In FIG. 2B, the second plug DP partially overlaps the insulating column 110, so the second plug DP is formed in part of the second insulating pillar 106 and the first insulating pillar 108, and the second insulating pillar 106 is in contact with the second plug DP; accordingly, the charge storage structure CS has a discontinuous ring shape due to the embedding of the first plug SP. Moreover, the distance s2 between the center of the first plug SP and the center of the second plug DP is required to be greater than the radius r2 of the vertical channel pillar VC to ensure that the first plug SP and the second plug DP are not short-circuited. In this embodiment, the charge storage structure CS of the vertical channel pillar VC is only embedded in the first plug SP, and the first plug SP and the second plug DP are opposite to each other. In FIG. 2B, the second plug DP is surrounded by the first insulating pillar 108 and embedded in the second insulating pillar 106, but is not limited thereto. In other embodiments, the first plug SP can be replaced by the second plug DP, and the second plug DP is surrounded by the first insulating pillar 108 and embedded in the second insulating pillar 106. The outer insulating layer 114 of the memory device 200 only surrounds the first plug SP outside the vertical channel pillar VC. The channel layer 112 and the charge storage structure CS are between the second plug DP and the conductive layer 104, so there is no need to provide an outer insulating layer 114 around the second plug DP. Compared with the previous embodiment, the distance s2 between the center of the first plug SP and the center of the second plug DP is shorter, so the overall dimension of the memory device 200 may be smaller than the memory device 100, thereby increasing the device density. In some embodiments, the channel layer 112 is located between the bottom SPb of the first plug SP and the insulating column 110, and the channel layer 112 is located between the second plug DP and the charge storage structure CS.

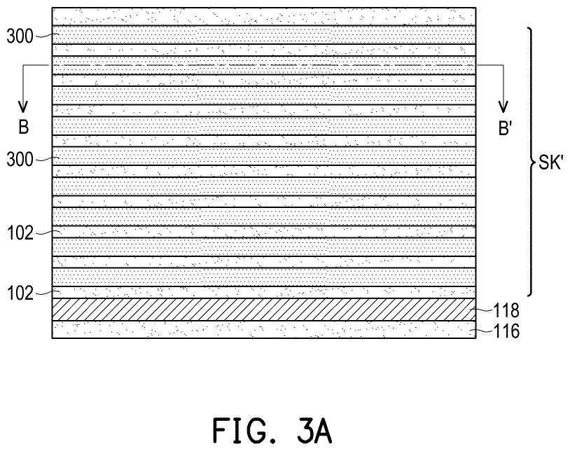

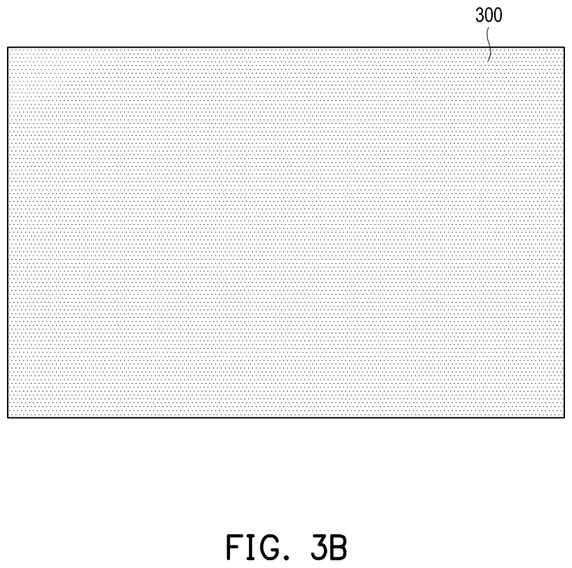

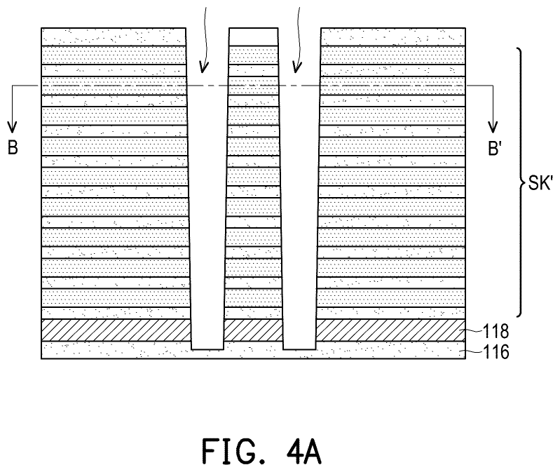

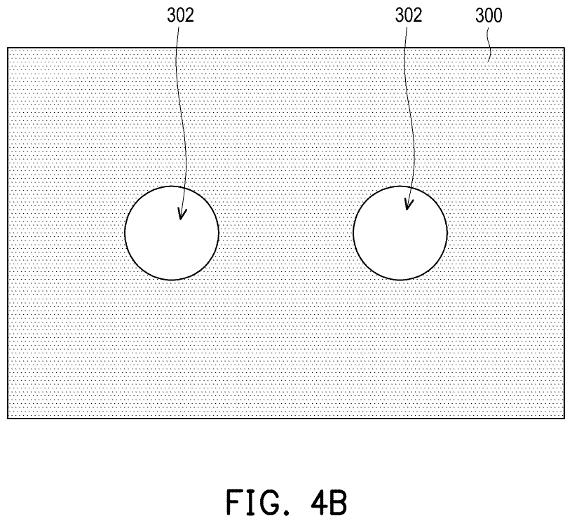

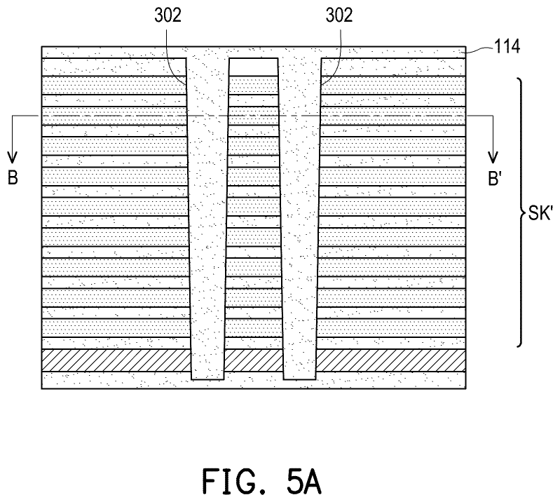

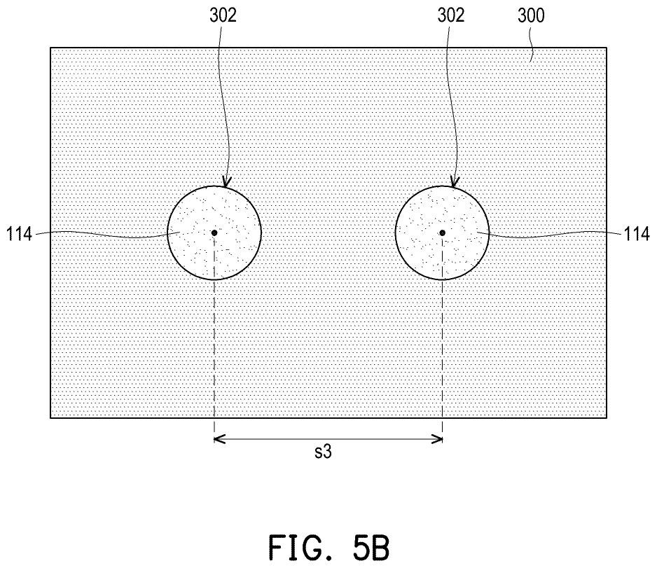

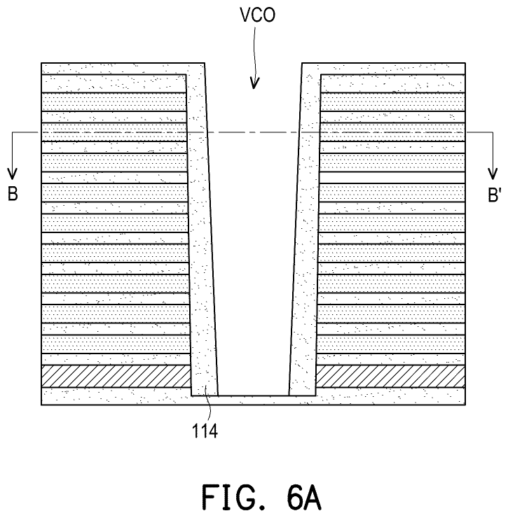

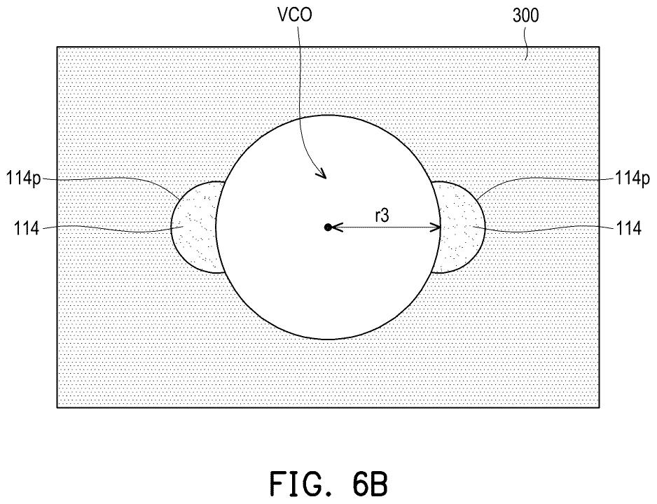

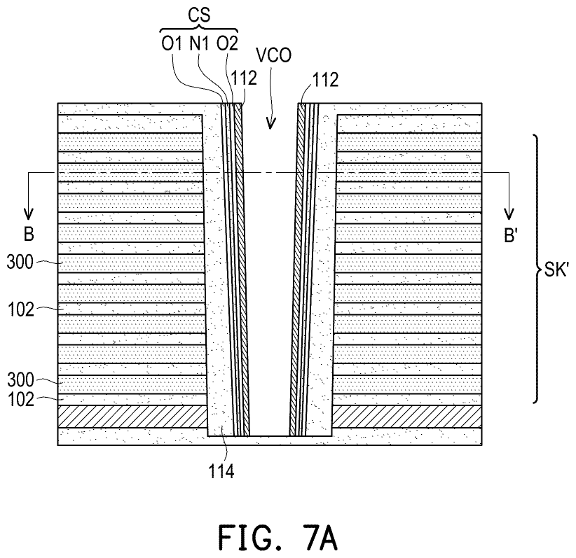

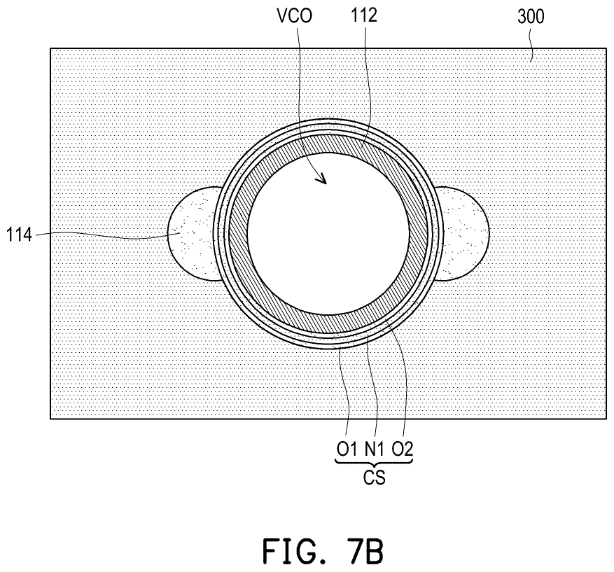

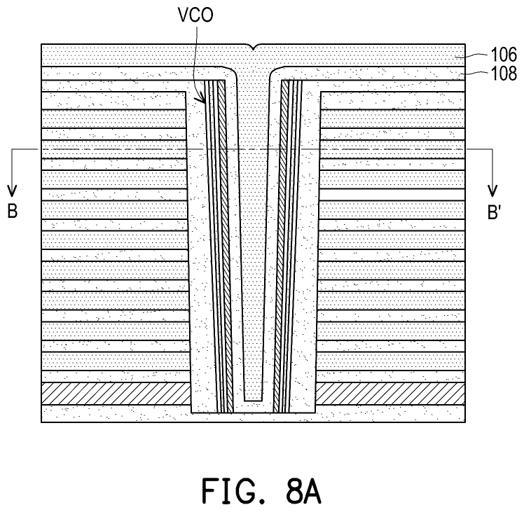

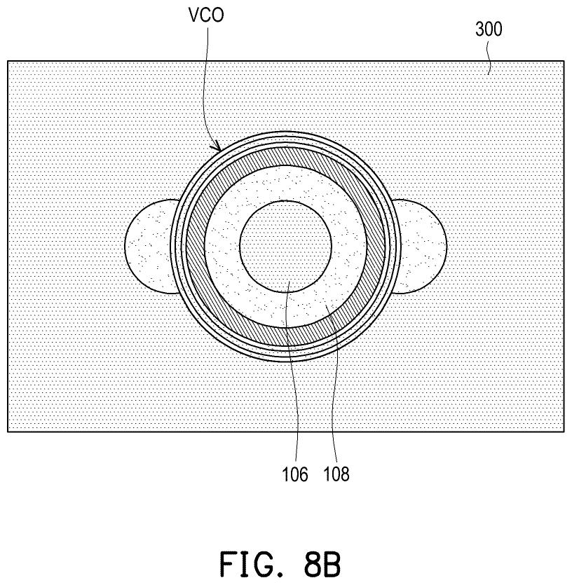

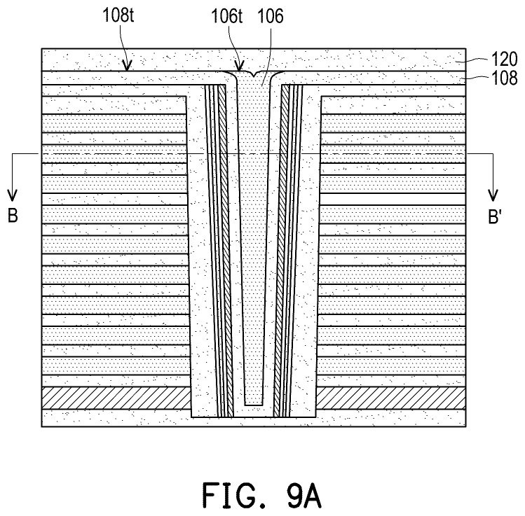

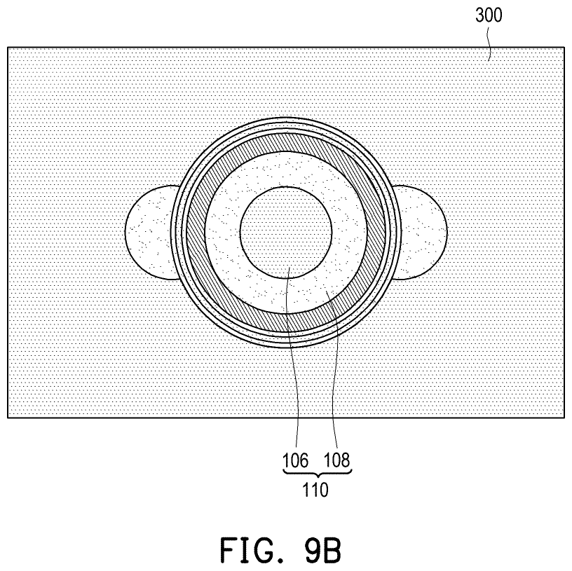

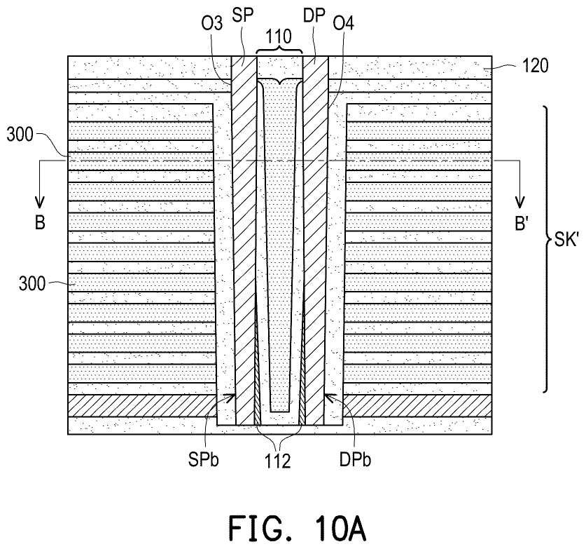

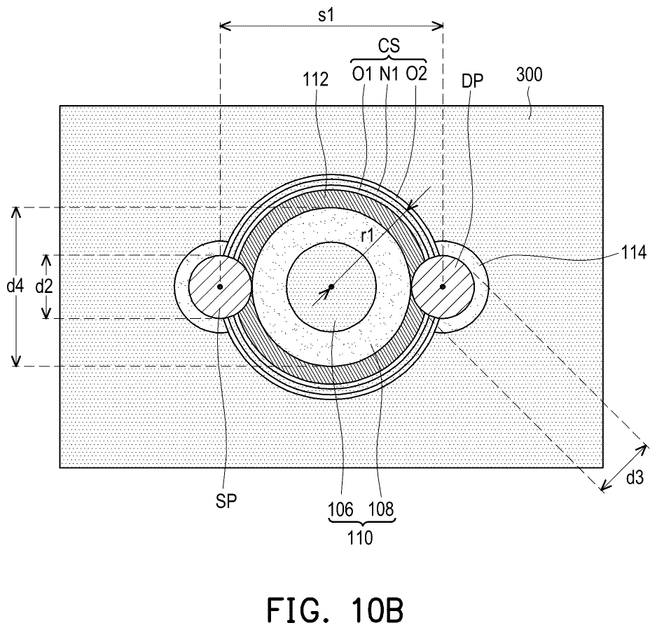

FIG. 3A, FIG. 4A, FIG. 5A, FIG. 6A, FIG. 7A, FIG. 8A, FIG. 9A, and FIG. 10A are section views of a manufacturing process of a memory device according to an embodiment of the disclosure. FIG. 3B, FIG. 4B, FIG. 5B, FIG. 6B, FIG. 7B, FIG. 8B, FIG. 9B, and FIG. 10B are top views of line B-B′ in FIG. 3A, FIG. 4A, FIG. 5A, FIG. 6A, FIG. 7A, FIG. 8A, FIG. 9A, and FIG. 10A respectively.

Referring to FIG. 3A and FIG. 3B, a stacked structure SK′ is first formed. The stacked structure SK′ includes stacked insulating layers 102 and sacrificial layers 300 that are alternately stacked. In some embodiments, the sacrificial layer 300 is, for example, polysilicon or other suitable material. In one embodiment, the material of the insulating layer 102 includes silicon oxide. The method of forming the stacked structure SK′ is, for example, but not limited to, alternately depositing the insulating layer 102 and the sacrificial layer 300 above the conductive layer 118 on the insulating layer 116.

Referring to FIG. 4A and FIG. 4B, two first through holes 302 penetrating the above-mentioned stacked structure SK′ are formed. The positions of the two first through holes 302 are the positions where the first plug and the second plug are expected to be formed. The method of forming the first through hole 302 is, for example, but not limited to, forming a hole penetrating through the stacked structure SK′ and the conductive layer 118 until exposing the insulating layer 116 using a lithography etching process.

Referring to FIG. 5A and FIG. 5B, an outer insulating layer 114 is formed in the first through holes 302. The distance s3 between the centers of the two first through holes 302 may be adjusted according to the device design, for example, adjusted to be similar to or consistent with the diameter of the vertical channel pillar formed subsequently, but not limited thereto.

Referring to FIG. 6A and FIG. 6B, a vertical channel hole VCO is formed penetrating the stacked structure SK′, and the vertical channel hole VCO exposes part of the outer insulating layer 114. The radius r3 of the vertical channel hole VCO is approximately equal to the radius of the subsequently formed vertical channel pillar. Although the vertical channel hole VCO in FIG. 6B is located in the center, the vertical channel hole VCO may be slightly offset to one side without affecting the performance of the final memory device. In some embodiments, the perimeter 114p of the outer insulating layer 114 extends beyond the perimeter of the vertical channel hole VCO.

Referring to FIG. 7A and FIG. 7B, the charge storage structure CS and the channel layer 112 are formed. The method of forming the charge storage structure CS is, for example, but not limited to, conformally depositing the oxide layer O1, the nitride layer N1 and the oxide layer O2 on the stacked structure SK′, and then removing the ONO composite layer outside and at the bottom of the vertical channel hole VCO by using anisotropic etching. In some embodiments, the material of channel layer 112 includes polysilicon. The method of forming the channel layer 112 is, for example, but not limited to, conformally depositing polysilicon on the charge storage structure CS and the stacked structure SK′, and then removing the polysilicon outside the vertical channel hole VCO and at the bottom of the vertical channel hole VCO by using anisotropic etching.

Referring to FIG. 8A and FIG. 8B, in order to form an insulating column, a first insulating pillar 108 may be conformally deposited first, and then the material of the second insulating pillar 106 may be filled in the vertical channel hole VCO. In some embodiments, the material of the second insulating pillar 106 is, for example, silicon nitride, and the material of the first insulating pillar 108 is, for example, high quality oxide (HQO).

Referring to FIG. 9A and FIG. 9B, the second insulating pillar 106 is planarized until its top surface 106t is substantially flush with the top surface 108t of the first insulating pillar 108. In some embodiments, the top surface 106t of the second insulating pillar 106 may be higher than the top surface 108t of the first insulating pillar 108 or lower than the top surface 108t of the first insulating pillar 108. The method of planarizing the second insulating pillar 106 includes, but is not limited to, a chemical mechanical planarization (CMP) process, a recess etching process, or a combination thereof. Then, for the subsequent etching process, at least one dielectric layer 120 may be formed overall.

Referring to FIG. 10A and FIG. 10B, a first plug SP and a second plug DP are formed on both sides of the insulating column (e.g., the first insulating pillar 108). The formation method is, for example, but not limited to, first forming the plug opening O3 and the plug opening O4, then depositing a conductive material therein, in which the conductive material is, for example, doped polysilicon, and then performing a planarization process. In some embodiments, a diameter d4 of the insulating column 110 is larger than the diameter d2 of the first plug SP or the diameter d3 of the second plug DP. In FIG. 10B, the distance s1 between the center of the first plug SP and the center of the second plug DP is greater than the radius r1 of the vertical channel pillar. Since the plug opening O3 and the plug opening O4 may be wide at the top and narrow at the bottom, in FIG. 10A, the channel layer 112 remains between the bottom SPb of the first plug SP and the insulating column 110, and the channel layer 112 also remains between the bottom DPb of the second plug DP and the insulating column 110. The charge storage structure CS is embedded in the first plug SP and the second plug DP, and the first plug SP and the second plug DP are opposite to each other.

Afterwards, a gate replacement process may be performed to replace the sacrificial layer 300 with the conductive layer 104 in FIG. 1A to produce the memory device 100 as shown in FIG. 1A to FIG. 1B.

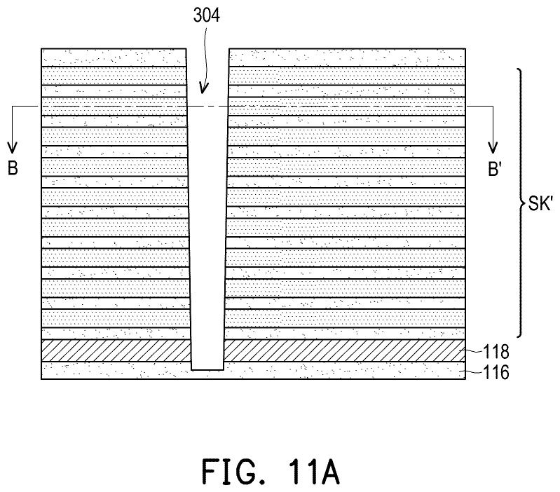

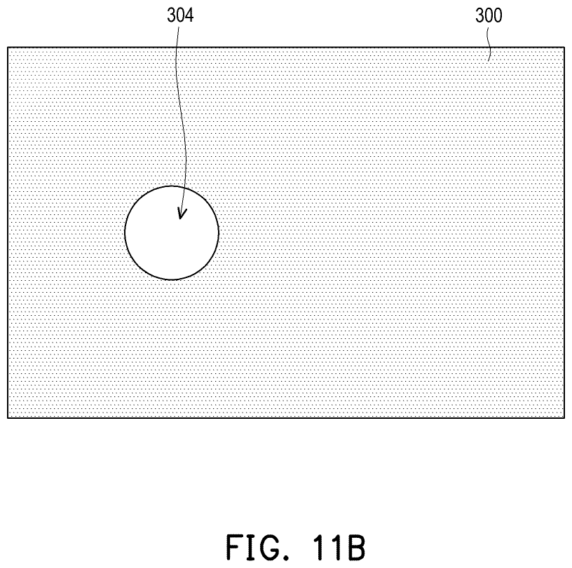

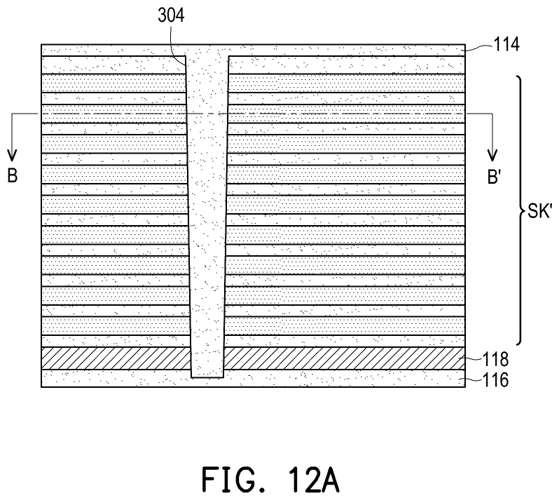

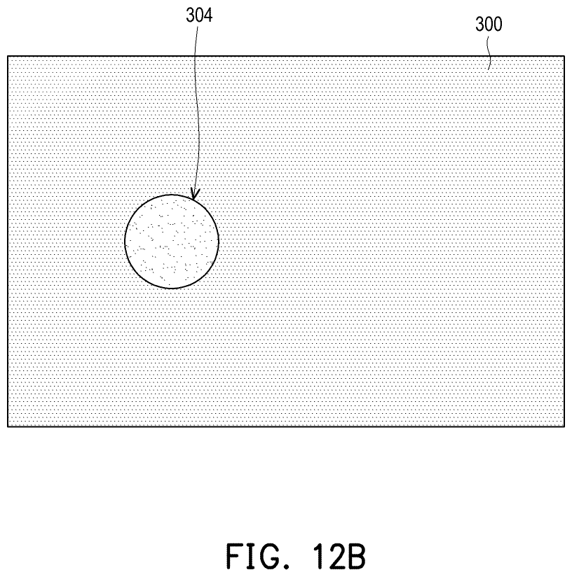

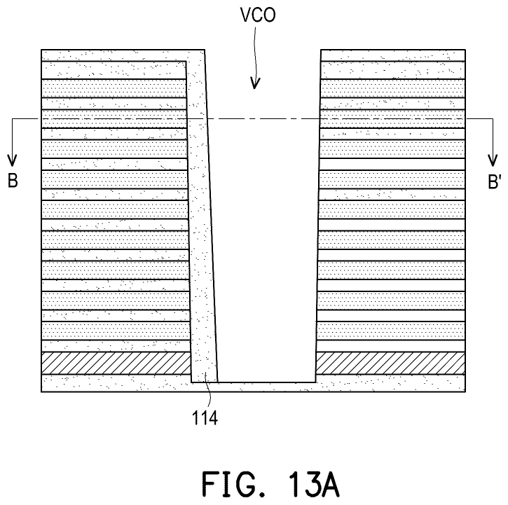

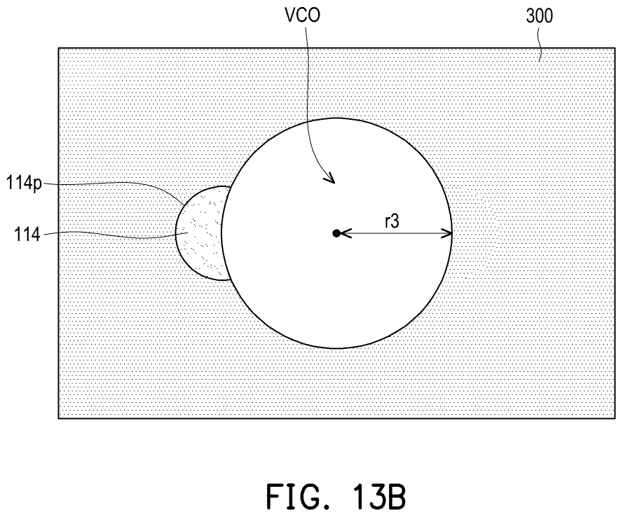

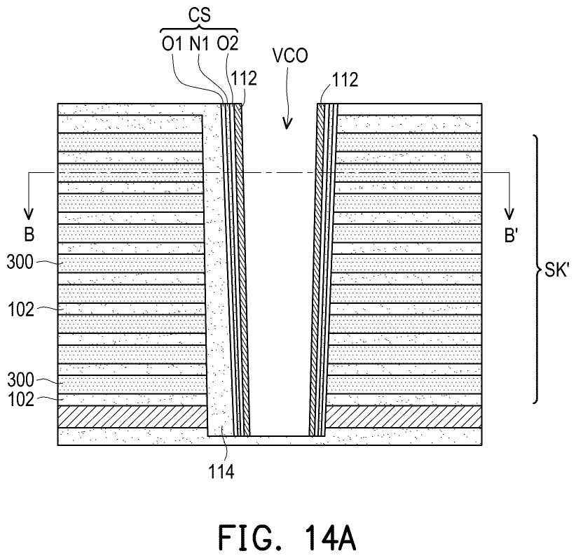

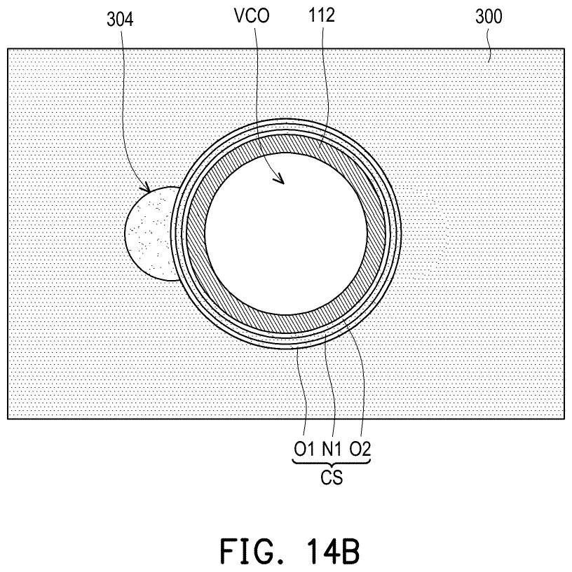

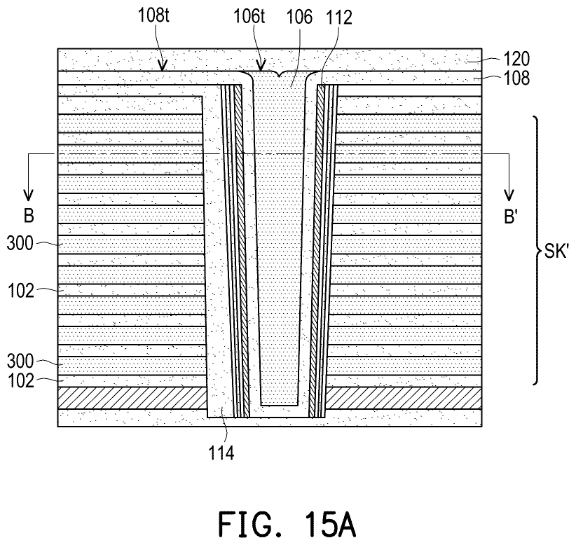

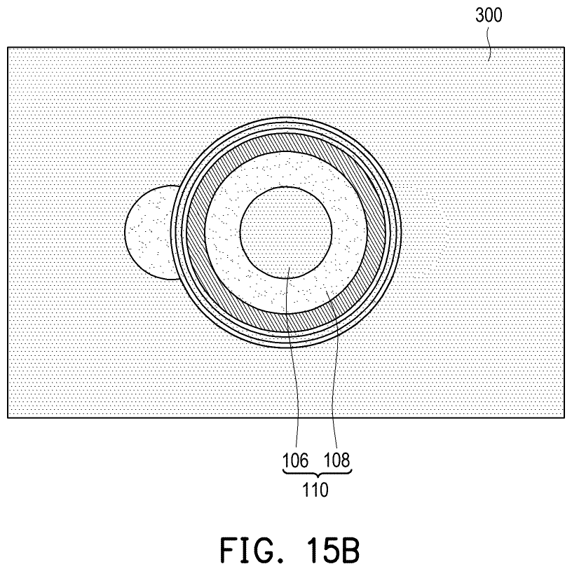

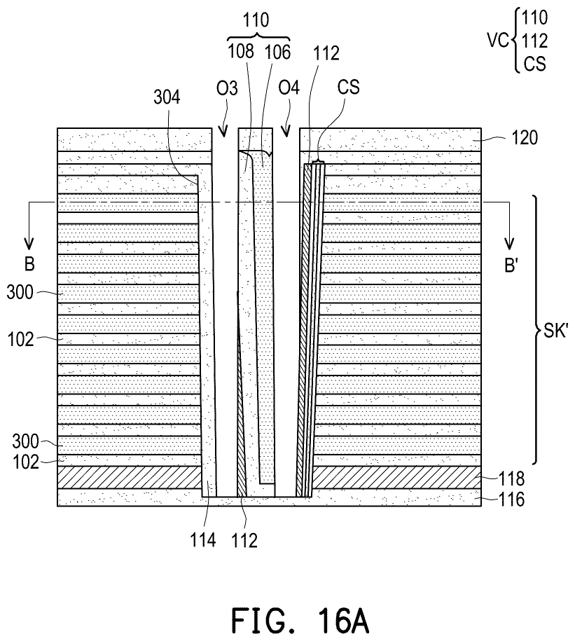

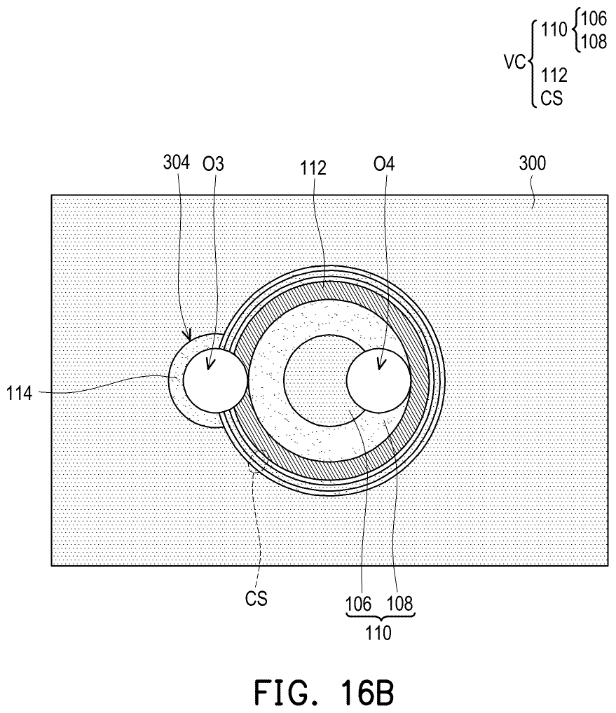

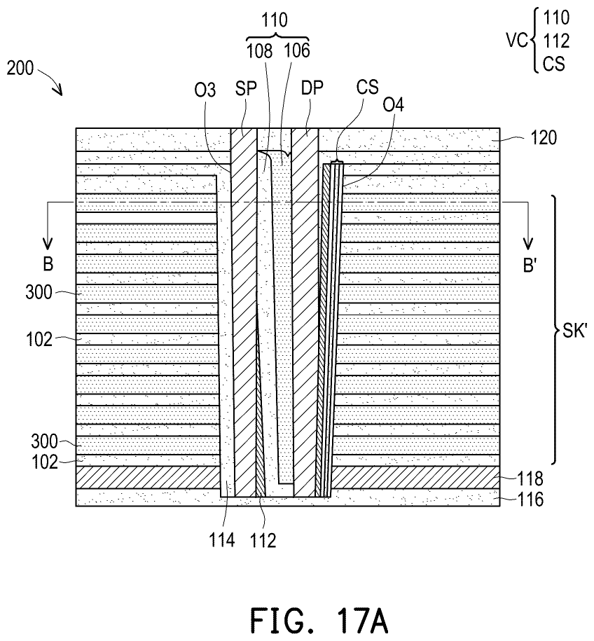

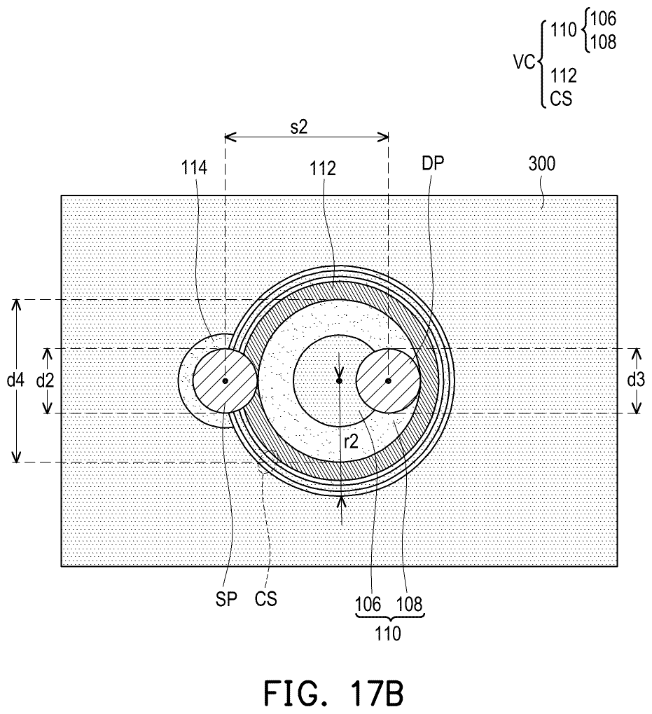

FIG. 11A, FIG. 12A, FIG. 13A, FIG. 14A, FIG. 15A, FIG. 16A, and FIG. 17A are section views of a manufacturing process of another memory device according to an embodiment of the disclosure. FIG. 11B, FIG. 12B, FIG. 13B, FIG. 14B, FIG. 15B, FIG. 16B, and FIG. 17B are top views of line B-B′ in FIG. 11A, FIG. 12A, FIG. 13A, FIG. 14A, FIG. 15A, FIG. 16A, and FIG. 17A respectively.

Referring to FIG. 11A and FIG. 11B, a stacked structure SK′ is first formed. The stacked structure SK′ includes stacked insulating layers 102 and sacrificial layers 300 that are alternately stacked. For the materials and formation methods of the insulating layer 102 and the sacrificial layer 300, reference may be made to the previous embodiment. A second through hole 304 penetrating the stacked structure SK′ is formed, and the position of the second through hole 304 is the position where the first plug is expected to be formed. For the formation method of the second through hole 304, reference may be made to the method used to form the first through hole 302 in the previous embodiment.

Referring to FIG. 12A and FIG. 12B, an outer insulating layer 114 is formed in the second through hole 304.

Referring to FIG. 13A and FIG. 13B, a vertical channel hole VCO is formed penetrating the stacked structure SK′, and the vertical channel hole VCO exposes part of the outer insulating layer 114. The radius r3 of the vertical channel hole VCO is approximately equal to the radius of the subsequently formed vertical channel pillar. In some embodiments, the perimeter 114p of the outer insulating layer 114 extends beyond the perimeter of the vertical channel hole VCO.

Referring to FIG. 14A and FIG. 14B, the charge storage structure CS and the channel layer 112 are formed, and reference may be made to the method of forming the charge storage structure CS and the channel layer 112 in the previous embodiment.

Referring to FIG. 15A and FIG. 15B, the insulating column 110 including a second insulating pillar 106 and a first insulating pillar 108 is formed, and reference may be made to the method of forming the insulating column 110 in the previous embodiment.

Referring to FIG. 16A and FIG. 16B, a plug opening O3 and a plug opening O4 are formed on both sides of the insulating column 110, in which the plug opening O3 is formed in a portion of the second through hole 304, and the plug opening O4 is formed within the vertical channel pillar VC.

Referring to FIG. 17A and FIG. 17B, a first plug SP is formed in the plug opening O3 and a second plug DP is formed in the plug opening O4. The distance s2 between the center of the first plug SP and the center of the second plug DP is greater than the radius r2 of the vertical channel pillar VC. Therefore, in this embodiment, the charge storage structure CS of the vertical channel pillar VC is only embedded in the first plug SP, and the first plug SP and the second plug DP are opposite to each other. In FIG. 17B, the second plug DP is surrounded by the first insulating pillar 108 and embedded in the second insulating pillar 106, but is not limited thereto; in other embodiments, the first plug SP can be replaced by the second plug DP, and the second plug DP is surrounded by the first insulating pillar 108 and embedded in the second insulating pillar 106. In some embodiments, the diameter d4 of the insulating column 110 is larger than the diameter d2 of the first plug SP or the diameter d3 of the second plug SP.

Afterwards, a gate replacement process may be performed to replace the sacrificial layer 300 with the conductive layer 104 in FIG. 2A to produce the memory device 200 as shown in FIG. 2A to FIG. 2B.

To sum up, the memory device and the method of manufacturing the same according to the embodiments of the disclosure enable contact between the first/second plug and the channel layer, improving the LBL open issue, without the need to consider LBL short yield loss. Moreover, the vertical channel pillar in the memory device of the embodiments of the disclosure may be shrunk to achieve higher device density. In addition, since the first/second plugs are not surrounded by the charge storage structure CS or the channel layer 112, it prevents undesirable interactions between the aforementioned structures and the first/second plugs, in contrast to previous devices where such devices were enclosed within the vertical channel pillar VC.

What is claimed is:

1. A memory device, comprising:
a stacked structure, comprising a plurality of insulating layers and a plurality of conductive layers that are alternately stacked;
a vertical channel pillar, vertically penetrating the stacked structure, wherein the vertical channel pillar comprises an insulating column, a channel layer surrounding the insulating column, and a charge storage structure surrounding the channel layer; and
a first plug and a second plug, arranged on both sides of the insulating column and connected to the channel layer, wherein
in a top view, a distance between a center of the first plug and a center of the second plug is greater than a radius of the vertical channel pillar.

2. The memory device according to claim 1, further comprising an outer insulating layer surrounding the first plug or the second plug outside the vertical channel pillar.

3. The memory device according to claim 2, wherein a perimeter of the outer insulating layer exceeds a perimeter of the vertical channel pillar.

4. The memory device according to claim 2, wherein the outer insulating layer is in contact with the charge storage structure.

5. The memory device according to claim 1, wherein the charge storage structure of the vertical channel pillar is embedded in one or both of the first plug and the second plug, and the first plug and the second plug are opposite to each other.

6. The memory device according to claim 1, wherein in the top view, the first plug or the second plug partially overlaps the insulating column.

7. The memory device according to claim 1, wherein a diameter of the insulating column is greater than a diameter of the first plug or a diameter of the second plug.

8. The memory device according to claim 1, wherein the insulating column comprises a second insulating pillar and a first insulating pillar surrounding the second insulating pillar.

9. The memory device according to claim 8, wherein the first plug and the second plug are opposite to each other and separated by the first insulating pillar.

10. The memory device according to claim 8, wherein one of the first plug and the second plug is surrounded by the first insulating pillar and embedded in the second insulating pillar.

11. The memory device according to claim 1, wherein the channel layer is located between a bottom of the first plug and the insulating column, and the channel layer is located between a bottom of the second plug and the insulating column.

12. The memory device according to claim 1, wherein the channel layer is located between a bottom of the first plug and the insulating column, and the channel layer is located between the second plug and the charge storage structure.

13. A method of manufacturing a memory device, comprising:
forming a stacked structure, the stacked structure comprising a plurality of insulating layers and a plurality of sacrificial layers that are alternately stacked;
forming a vertical channel pillar penetrating the stacked structure, wherein the vertical channel pillar comprises an insulating column, a channel layer surrounding the insulating column, and a charge storage structure surrounding the channel layer;
forming a first plug and a second plug on both sides of the insulating column, wherein the first plug and second plug are connected to the channel layer, and a distance between a center of the first plug and a center of the second plug is greater than a radius of the vertical channel pillar; and
performing a gate replacement process to replace the plurality of sacrificial layers with a plurality of conductive layers.

14. The method of manufacturing the memory device according to claim 13, wherein before forming the vertical channel pillar further comprises:
forming two first through holes penetrating the stacked structure, wherein positions of the two first through holes are positions of the first plug and the second plug, and a perimeter of the two first through holes exceeds a perimeter of the vertical channel pillar; and
forming an outer insulating layer in the two first through holes.

15. The method of manufacturing the memory device according to claim 14, wherein forming the first plug and the second plug comprises forming the first plug and the second plug in a portion of the two first through holes.

16. The method of manufacturing the memory device according to claim 13, wherein before forming the vertical channel pillar further comprises:
forming a second through hole penetrating the stacked structure, wherein a position of the second through hole is a position of the first plug, and a perimeter of the second through hole exceeds a perimeter of the vertical channel pillar; and
forming an outer insulating layer in the second through hole.

17. The method of manufacturing the memory device according to claim 16, wherein forming the first plug and the second plug comprises:
forming the first plug in a portion of the second through hole; and
forming the second plug within the vertical channel pillar.

18. The method of manufacturing the memory device according to claim 13, wherein the charge storage structure of the vertical channel pillar is embedded in the first plug and the second plug or one of the two, and the first plug and the second plug are opposite to each other.

19. The method of manufacturing the memory device according to claim 13, wherein a diameter of the insulating column is greater than a diameter of the first plug or a diameter of the second plug.

20. The method of manufacturing the memory device according to claim 13, wherein the insulating column comprises a first insulating pillar and a second insulating pillar, and the first insulating pillar surrounds the second insulating pillar.
